(19) United States
(12) Patent Application Publication
(10) Pub. No.: US 2014/0191115 A1
(43) Pub. Date: Jul. 10, 2014

(54) SPAD SENSOR CIRCUIT WITH BIASING CIRCUIT

(71) Applicants: THE UNIVERSITY COURT OF THE UNIERSITY OF EDINBURGH, Edinburgh (GB); STMICROELECTRONICS (RESEARCH & DEVELOPMENT) LIMITED, Marlow (GB)

(72) Inventors: Eric Alexander Garner Webster, Edinburgh (GB); Robert K. Henderson, Edinburgh (GB)

(73) Assignees: THE UNIVERSITY COURT OF THE UNIERSITY OF EDINBURGH, Edinburgh (GB); STMICROELECTRONICS (RESEARCH & DEVELOPMENT) LIMITED, Marlow (GB)

(21) Appl. No.: 14/150,346

(22) Filed: Jan. 8, 2014

(30) Foreign Application Priority Data
Jan. 9, 2013 (GB) 1300334.8

(51) Int. Cl. H01L 31/107

(52) U.S. Cl. CPC H01L 31/107
USPC 250/214 R

(57) ABSTRACT

A deep SPAD structure uses the substrate as the anode terminal of its multiplication p-n junction. A bias voltage for the SPAD (in excess of the SPAD's breakdown voltage) is coupled to the SPAD's cathode terminal. The bias voltage is generated by a charge pump circuit which is also integrated on the substrate. The charge pump circuit is configured to isolate the bias voltage on the cathode terminal. A triple well CMOS process is used to isolate the transistors of the charge pump circuit from the substrate.

### PRIORITY CLAIM

This application claims priority from Great Britain Application for Patent No. 1300334.8 filed Jan. 9, 2013, the disclosure of which is incorporated by reference.

### TECHNICAL FIELD

This application relates to sensor circuits which comprise a Single-Photon Avalanche Diode (SPAD) and in particular to such circuits providing active recharge of the SPAD.

### BACKGROUND

The avalanche process in solid-state devices has been known since 1953, as has its application to photo-multiplication. An avalanche is triggered when reverse biasing a PN-junction to around the breakdown voltage. This effect can be used in two modes of operation. Commonly, the avalanche photodiodes are biased just below the breakdown voltage, the photocurrent remaining proportional to the incoming light intensity. Gain values of a few hundreds are obtained in III-V semiconductors as well as in silicon.

Single-Photon Avalanche Diodes (SPADs) are solid-state photo detectors which utilize the fact that p-n diodes can be stable for a finite time above their breakdown voltage. When an incident photon with sufficient energy to liberate an electron arrives, avalanche multiplication of the photo-generated electron occurs due to the high electric field. This produces a measurable current pulse signaling the arrival of the photon which negates the need for amplification due to the internal gain of the device.

Essentially SPADs are photodiodes that are biased above the breakdown voltage in the so-called Geiger mode. This mode of operation requires the introduction of a quenching mechanism to stop the avalanche process. Each incoming photon results in a strong current pulse of few nanoseconds duration. The device works in a way that resembles, in some respects, an optical Geiger counter.

Single photon counting devices have only recently been successfully integrated in CMOS technologies opening the way to non-photomultiplier tube (PMT) based fully solid-state single photon sensing devices.

Conventionally, SPADs are sensitive at short wavelengths, which is largely due to the use of shallow source-drain implants to form the avalanche region. SPADs have been created in a variety of CMOS geometries from 0.8 μm to 65 nm. Process variants such as Silicon-on-Insulator (SOI), high voltage and BiCMOS process variants have been employed, making use of additional wells and implants to create suitable guard ring structures and avalanche breakdown regions.

Recently there has been developed a SPAD design (hereinafter referred to as Deep SPAD) which addresses the issue of improving red and NIR (long wavelength) sensitivity in standard CMOS processes. This is described in published PCT Application No. PCT/GB2011/051686 (the disclosure of which is incorporated by reference). Modern CMOS processes are fabricated on an epitaxial layer grown on top of a substrate which results in decreasing doping concentration towards the surface. This feature is combined with the diffusion and implantation characteristics of the n-well and deep n-well (DNW) implants to create the cathode and guard ring. The implanted ions diffuse during subsequent processing steps, creating lower doped regions at the edges of the Deep SPAD which acts as a guard ring. Additionally the guard ring structure may use a p-well blocking layer to create a space between n-well and p-well implants where p-well formation is prohibited. Moreover, the prohibited p-well space is not above a deep n-well implant and is adjacent to the biased region of the device. The net result is a SPAD in CMOS which has a deeper junction and thus much improved long wavelength sensitivity due to the electromagnetic properties of light.

Red and NIR response is a particularly important feature for SPADs because of two main application areas: range detection and lifetime analysis. NIR wavelengths of 850 nm are commonly used in ranging systems because this is invisible to the human eye. Moreover, SPADs have been used in biological experiments for lifetime estimation which potentially may have cell-sorting applications. However, a fundamental problem of existing SPADs is that their peak detection efficiency is blue light. Since blue corresponds to high energy photons, it has the disadvantage of killing the cells which are to be observed. Red light, as it is of lower energy, does not have this problem. Additionally, red sensitivity improvements allow the use of SPADs in digital communication systems using optical fibers because the attenuation of red light is lower than blue light.

As mentioned above, SPAD operation requires quenching. Quenching is required to stop the avalanche process, which is done by reducing the SPAD's reverse bias below its breakdown voltage. The simplest quenching circuit is commonly referred to as passive quenching. Usually, passive quenching is simply performed by providing a resistance in series to the SPAD. The avalanche current self-quenches simply because it develops a voltage drop across the resistance (a high-value ballast load), reducing the voltage across the SPAD to below its breakdown voltage. After the quenching of the avalanche current, the SPAD's bias slowly recovers to at or above the breakdown voltage and the detector is ready to be triggered again.

An alternative to passive quenching is active quenching. There are a number of different active quenching arrangements, although in general active quenching refers to detection of a breakdown event by some subsequent digital logic connected to the SPAD output, and actively pulling the SPAD moving node to a voltage below breakdown, quenching the avalanche. Active quenching is desirable for several reasons such as reduced dead time, the ability to time gate the SPAD, and improved photon counting rate at high light levels enabling a dynamic range extension. Active quenching is essential in many applications of SPAD technology.

An active quench circuit for is not available for the above described Deep SPAD, or any other high voltage positively driven SPAD implemented in a triple-well CMOS process, at present.

It is desirable to be able to provide active quenching for such a Deep SPAD design.

### SUMMARY

In a first aspect there is provided a sensor circuit comprising: a single photon avalanche diode (SPAD), requiring application of a bias voltage to operate; a charge pump final stage operable to generate said bias voltage from a first voltage and a second voltage, said bias voltage being higher than the breakdown voltage of the SPAD junction, each of said first voltage and said second voltage being lower than the breakdown voltage of the SPAD junction; wherein said final stage is operable to isolate the bias voltage on an electrode of the SPAD, thereby biasing said SPAD.

Said charge pump final stage and said SPAD may be on a common substrate. Said common substrate may form one half of the SPAD's multiplication junction.

Said circuit may be operable such that the bias voltage is stored on the SPAD's capacitance, which comprises the junction capacitance, coupling capacitance, and any parasitic capacitance. Said final stage may be operable to isolate the bias voltage on the SPAD's cathode.

Said final stage may comprise at least one diode at its output to isolate said bias voltage on the SPAD's electrode. Said at least one diode may be integrated within the SPAD. Said diode may comprise a diode implant formed within an implant which forms one half of the SPAD's multiplication junction. Alternatively said diode may be comprised within a separate well implant. Said circuit may comprise a capacitor operable to DC-isolate output devices from said bias voltage, wherein said second voltage is applied to the SPAD's electrode via said capacitor.

Said final stage may be operable to stack the said first and second voltages on one of its nodes so as to generate said bias voltage. Said charge pump final stage may comprise one or more devices isolated from said substrate in a well implant. Said node may comprise a drain or source implant of a MOSFET device. In particular, the charge pump final stage may comprise NMOS transistors isolated from the substrate inside a p-well or PMOS transistors isolated from the substrate inside an n-well. Said node on which said voltage is stacked in order to generate the bias voltage may comprise a drain or source implant of one of said NMOS transistors.

Said final stage may be operable in alternate phases of charging a capacitance with said first voltage and outputting the voltage stored on said capacitance in series with said second voltage. In one specific embodiment, the final stage comprises two capacitances and four MOSFET devices, a first two of said MOSFET devices being operable to selectively connect the first voltage to respective ones of said capacitances and a second two of said MOSFET devices acting as diodes being operable to isolate the voltage on the SPAD cathode from the output of said output stage.

Said circuit may be operable such that the charge pump final stage is enabled at periodic intervals. Said periodic intervals may be selected to be sufficient to counteract leakage from the SPAD cathode. Alternatively said circuit may comprise means operable to sense that the SPAD has triggered and on sensing such a trigger event, actively enabling the charge pump. In the latter case, the circuit may further comprise means operable to enable a correlated emission source.

In an embodiment said charge pump may provide a biasing voltage for a further transistor, connected between said charge pump and the SPAD cathode, said further transistor being configured to operate as a quenching resistor. Said further transistor may be provided within a well implant comprised within said SPAD.

Said second voltage may be provided by a periodic clock signal. Said final stage may be double-sided with said second voltage being provided by two non-overlapping periodic clock signals, the final stage being operable to pump on positive and negative edges of one of said clock signals.

Said sensor circuit may comprise: a plurality of SPAD's; a plurality of charge pump final stages; and a single charge pump operable to generate said first voltage for each of the charge pump final stages.

Each SPAD may comprise a dedicated charge pump final stage.

### BRIEF DESCRIPTION OF THE DRAWINGS

Embodiments of the invention will now be described, by way of example only, by reference to the accompanying drawings, in which:

FIG. 1 illustrates a passive quenching circuit with AC-coupling for a positively driven SPAD;

FIG. 2 illustrates an active recharge circuit for a positively driven SPAD according to a first embodiment of the invention;

FIG. 3 shows example clock and notclock input signals for the active recharge circuit of FIG. 2;

FIGS. 4A and 4B illustrate how the active recharge circuit of FIG. 2 operates at different phases

FIG. 5 illustrates the physical structure of a charge pump usable in the active recharge circuit of FIG. 2;

FIG. 6 illustrates an active recharge circuit for a positively driven SPAD according to a second embodiment of the invention;

FIG. 7 illustrates the physical structure of a charge pump usable in the active recharge circuit, integrated with the Deep SPAD of FIG. 6; and

FIG. 8 illustrates an alternative physical structure of a charge pump usable in the active recharge circuit of FIG. 6.

### DETAILED DESCRIPTION OF THE DRAWINGS

The terms active quench and active recharge are often used interchangeably. Indeed, the term ‘quenching’ is often used incorrectly and/or to refer to the recharging process instead. Active quench means that soon after a breakdown event is detected by some subsequent digital logic connected to the SPAD output, the SPAD moving node is actively pulled to a voltage below breakdown, quenching the avalanche. Active quench was mostly developed initially for discrete SPADs which had large capacitances, slow breakdowns, long dead-times and high after-pulsing probability. Active quench gains little performance with fully integrated SPADs in CMOS because the breakdown time is comparable to the switching time period of a MOS device and the after-pulsing probability of integrated SPADs is very low.

Active recharge refers to the ability to actively switch the SPAD above breakdown voltage after a delay generated from some digital logic connected to the SPAD output. The benefits of active recharge are pronounced, even in CMOS integrated SPADs. Active recharge enables variable control over the dead time and hence the after-pulsing probability. Importantly, active recharge enables the SPAD to operate at higher light levels than can be achieved with passive recharge. This is because active recharge drives the output of the SPAD past the digital logic threshold on each recharge event. Passive quench, by comparison, has an R-C recharge time constant and can break down again before the digital logic threshold is reached. This can lead to saturation and eventually reduction in the number of photons detected by a passively recharged SPAD as the light level is increased. This means that the photon count does not track the light level linearly which causes problems in some applications. With active recharge the SPAD output has a more linear photon count response to light level.

Moreover, active recharge further improves the photon detection probability (PDP) of a detector as it prevents the non-linear increase in electric field in the device which arises from an R-C recharge. Passively recharged devices suffer from reduced photon detection probability after the inverter threshold is passed but before the total excess bias is reached. Whereas in an actively quenched system, because the rise to above breakdown is near instantaneous, there is almost no period of time when the PDP is changing and the SPAD is armed.

Additionally, active recharge enables SPADs to be used in ‘time-gated’ mode. Time gating is often used in some ranging techniques where the SPAD is ‘armed’ at the same time or after a correlated light source is pulsed as this can improve the signal to noise ratio or simplify the digital processing.

However, the fundamental disadvantage of all active quench and active recharge circuitry is that they take up much more space than a simple passive quench component in most cases. The large area requirements of active quench/recharge reduce the fill factor of SPAD arrays and therefore reduce the sensitivity to light. Therefore, the use of passive or active quench is a classic engineering trade-off and which approach is better depends on the target application.

The Deep SPAD structure uses the substrate as one half of its multiplication p-n junction. Because of this, the anode terminal has to be common to the rest of the chip (usually ground). Therefore, the only method of connecting a bias voltage to the SPAD is to the cathode terminal, which requires a positive polarity in order to reverse bias the diode (obviously this is reversed for an n-type substrate). The breakdown voltage of such a SPAD constructed from deep n-well (DNW) and the substrate will usually be relatively high because of the low doping concentrations involved.

However, the high positive breakdown voltage of the proposed device is not compatible with standard CMOS transistor gates. Therefore, one method of creating a high voltage compatible ‘quench’ resistor in CMOS is to use a highly resistive polysilicon resistor to connect the cathode of the SPAD to a positive breakdown voltage supply. Moreover, the SPAD cathode, which is the moving node that falls in response to the avalanche current, cannot be directly connected to the CMOS inverter gates because it is also at a high DC bias level. Therefore, it is required to AC-couple the SPAD moving node to subsequent digital CMOS logic to ensure DC compatibility.

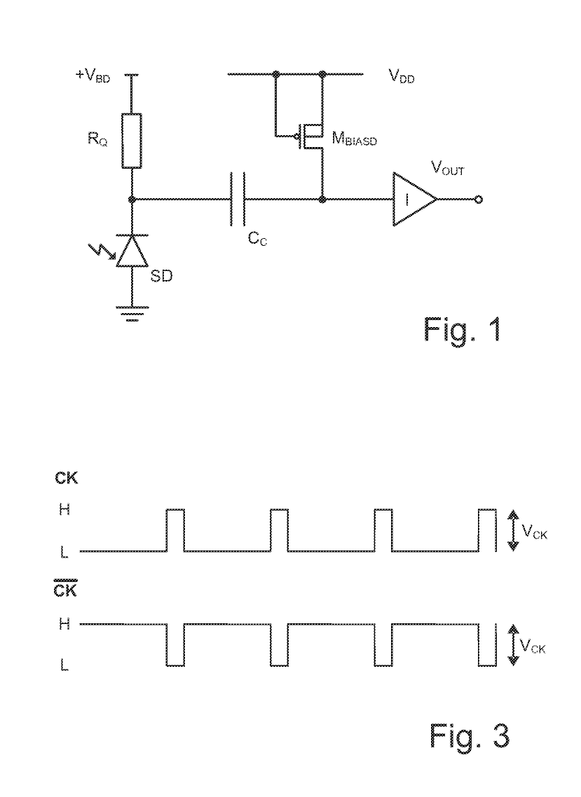

FIG. 1 illustrates such a passive quenching circuit for a Deep SPAD. The Deep SPAD is reversed bias by a relatively high positive bias voltage V_{BD} through polysilicon ballast resistor R_{Q}. A coupling capacitor C_{C} provides DC isolation from the SPAD's bias voltage V_{BD} plus an excess bias and a CMOS-compatible DC level is maintained via bias device M_{BIASD}.

The Deep SPAD structure complicates the active quench versus passive quench trade off more than that simply given above. This is because the highly resistive poly resistor takes up significantly more space in CMOS than a MOSFET device which is normally used as a quench resistor in traditional CMOS SPADs. Moreover, high voltage capacitors are generally more compact than high voltage resistors so it is favorable to use capacitors rather than poly resistors where possible.

For low cost and simple integration of SPADs into CMOS products it needs to be possible to generate the high breakdown voltage supply on chip. This presents a problem for the Deep SPAD structure because any high voltage supply would generate the high voltage on the DNW-substrate or n⁺-p-well diode. Therefore, the SPAD junction and supply would break down at the same voltage (or lower for n⁺-p-well) making Geiger-mode operation impossible.

It is therefore proposed to use a hybrid of active quench and charge pump circuit theory. Charge pumps are circuits which provide the ability to generate voltages higher than the chip supply voltage by using capacitors and switches or diodes in multiple stages, and are well known in the art. The connection of the MOS devices in charge pumps allows operation at high voltages by ensuring that each MOS transistor only ever sees a voltage difference within its allowed specification, while every terminal sits at the same common DC-bias level. For example, this means that a 3.3V rated NMOS transistor could safely conduct if the body was at 10V, source at 10V, drain at 13.3V, and the gate at 13.3V. The cascading of MOS-devices like a charge pump allows switching operation to occur at high voltage so as to be able to actively drive the Deep SPAD.

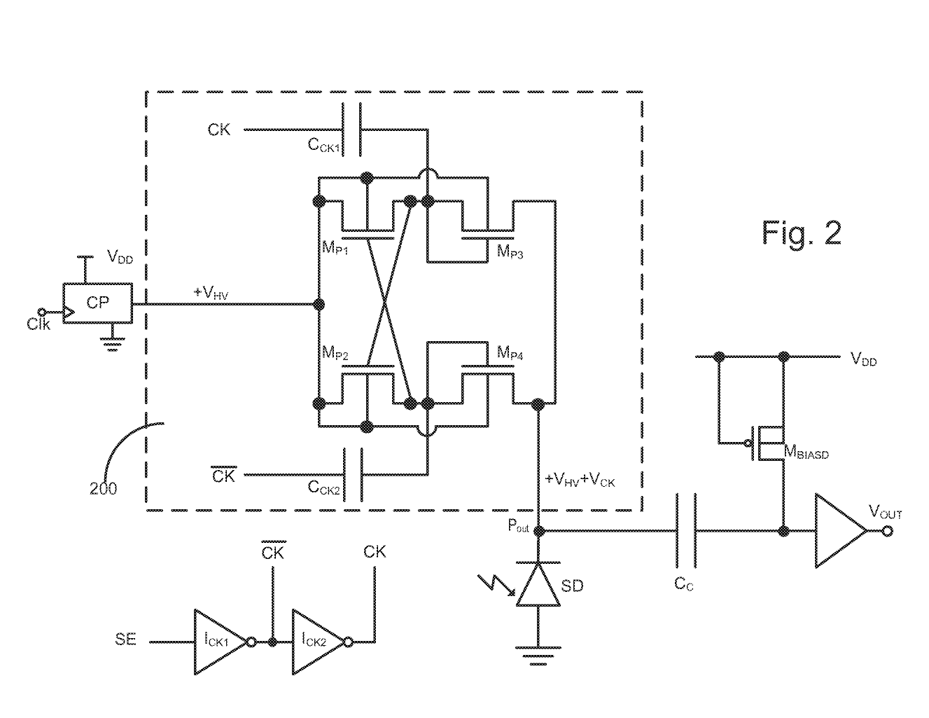

FIG. 2 shows a circuit schematic for an embodiment comprising a charge pump final stage 200, the Deep SPAD SD and the output circuitry of FIG. 1. It should be noted that the specific final stage shown here, while having some specific advantages as will be described, is shown for illustrative purposes, and other charge pump arrangements may be used instead.

Triple-well CMOS processes offer the ability to isolate NMOS transistors from the substrate inside their own p-well surrounded by n-well and deep n-well (DNW). Indeed, it is the deep n-well feature that allows the Deep SPAD to work. Therefore, the active quench and active recharge circuit makes it possible to store the high voltage on an NMOS's n⁺ source/drain implant inside its own p-well. The n⁺-p-well diode inside the DNW-substrate diode enables voltages to be pumped above the breakdown voltage of the DNW-substrate junction by a clock voltage at each stage of the charge pump.

Charge pump final stage 200 comprises two capacitances C_{CK1}, C_{CK2} and four NMOS transistors: two in cross-coupled configuration M_{P1}, M_{P2}, and two in diode configuration M_{P3}, M_{P4}. A high voltage bias signal V_{HV}, which is at a level below the breakdown voltage of the DNW-substrate junction of SPAD SD, is provided from a standard high-efficiency charge pump or external high positive voltage supply. In particular, the high voltage bias signal V_{HV} may be obtained from an on-chip charge pump CP which, because it shares the same substrate as the SPAD SD, should not be allowed to generate voltages at or above the breakdown voltage of the DNW-substrate junction. Non-overlapping clocks CK, C̅K̅ are generated from a SPAD enable signal SE by a chain of inverters I_{CK1}, I_{CK2}. The two cross-coupled NMOS transistors M_{P1}, M_{P2} are used to connect voltage V_{HV} through to their corresponding capacitance C_{CK1}, C_{CK2} on opposite phases of the clock.

It is preferable to use short duty cycle edges so that the transition on the SPAD node is fast as the voltage is pumped on the positive edges of clock CK and notclock C̅K̅ signals. FIG. 3 shows example clock CK and notclock ( C̅K̅) signals. As can be seen, when either signal is high it is at a level V_{CK}.

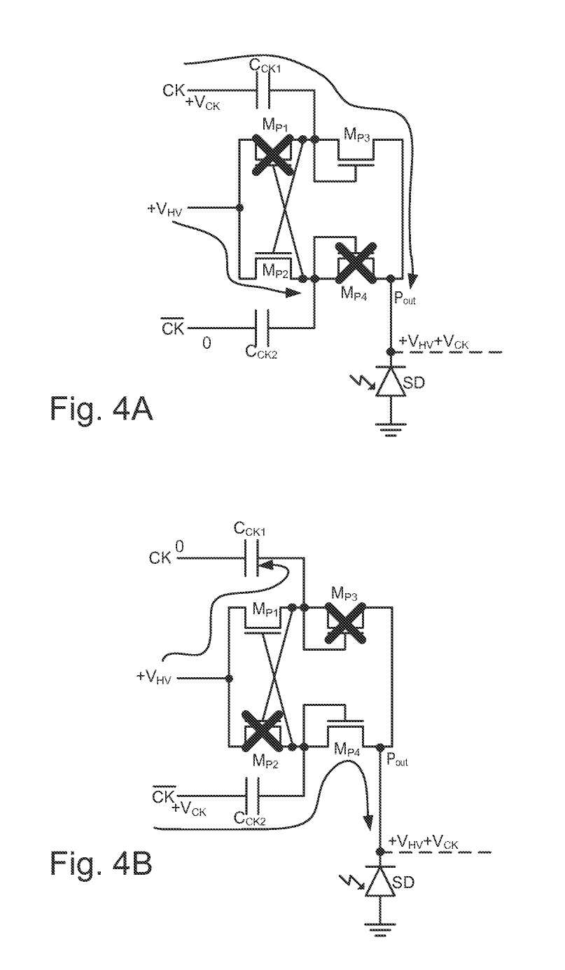

FIGS. 4A and 4B illustrate how the charge pump final stage circuit works (substrate connections have been removed for clarity). In FIG. 4A, clock signal CK has just gone high and simultaneously notclock signal C̅K̅ has gone low. This results in transistors M_{P2} and M_{P3} being switched on, and transistors M_{P1} and M_{P4} being switched off. The effect of this is that capacitor C_{CK2} is charged to +V_{HV}. Simultaneously transistor M_{P3} conducts the sum of the voltage on capacitor C_{CK1} (which will have been charged on a previous cycle) and the notclock signal voltage V_{CK} to the n+ drain implant of the MOS device M_{P3} and through to the SPAD SD cathode, which is consequently charged to V_{HV}+V_{CK} (equivalent to V_{BD} of FIG. 1). After clock CK returns low, the transistor M_{P3} turns off, and the high voltage is isolated on the SPAD SD node until the SPAD SD receives a photoelectron (or dark count electron) and breaks down. At which point, the voltage is driven down by the SPAD SD towards ground until the SPAD SD quenches itself and returns to a high resistance state just below breakdown. FIG. 4B shows the reverse situation, when notclock signal CK has just gone high and clock signal CK has gone low. It should be noted that the cross-coupling of transistors M_{P1} and M_{P2} enhances the efficiency of the output stage as voltage is pumped on both the positive and negative edges, although a single sided circuit is possible.

A sensor may comprise an array of SPADs, all biased by a single high voltage charge pump via a plurality of final stages 200, with the single high voltage charge pump generating a voltage just below the SPAD breakdown voltage, and each individual stage generating the remaining breakdown voltage. In one such embodiment, every SPAD is biased via a dedicated final stage.

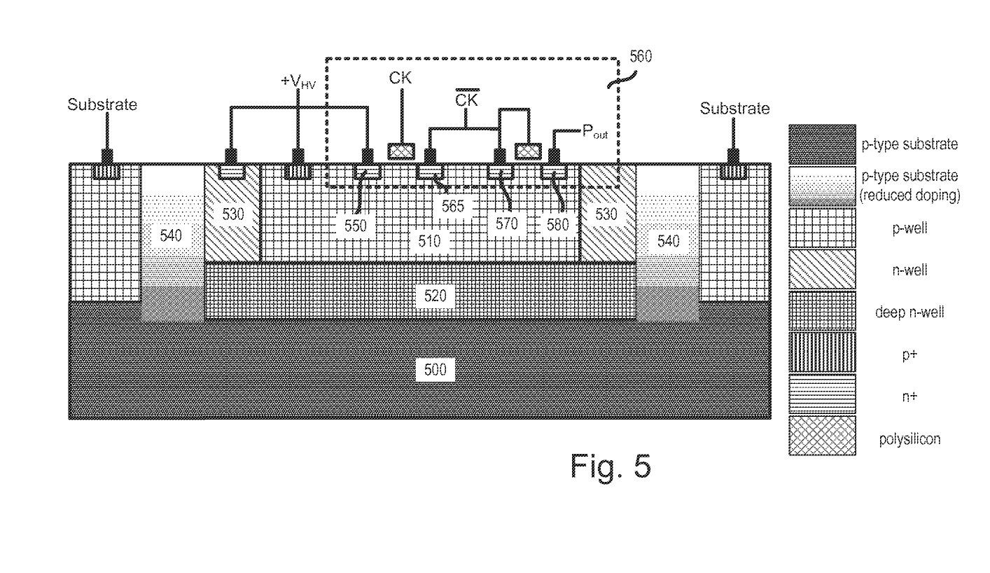

FIG. 5 shows a layout cross section of the charge pump 200 illustrating the triple well diode isolation of the high voltage. It shows a p-type substrate 500 in which is formed a p-well implant 510, surrounded by a deep n-well implant 520 below and n-well implants 530 either side. An area 540 of said substrate around the periphery of n-well 530 is formed with reduced p-doping to form a guard ring. NMOS devices 560 are formed inside of the p-well with connections as shown. In addition the p-well 510 body terminal of the NMOS devices is connected to bias voltage V_{HV} which is also connected to the n-well 530/deep n-well 520 isolation ring. This is because the p-well 510 cannot be allowed to go more positive than the deep n-well 520 as the junction would then be in a forward conduction condition. By using this arrangement, the excess bias voltage is stored on the n+ source/drain implant of an NMOS transistor isolated from the substrate in its own p-well. When signal CK goes high (and C̅K̅ goes low), the voltage V_{HV} on implant 550 is transferred to implant 565 and implant 570. When CK goes low (and C̅K̅ goes high), the voltage V_{HV} on implant 570 plus the clock voltage V_{ck} of signal C̅K̅ is transferred to implant 580, which is the output Pₒᵤₜ of the charge pump.

As with the Deep SPAD, a guard ring is required around the outside of the charge pump to prevent the lateral junction between p-well and n-well breaking down before the SPAD DNW-substrate junction. As already mentioned, the guard ring in this example is achieved by reducing the p-doping around the periphery of n-well by preventing p-well formation. However, any other guard ring constructions, including all those described in patent application PCT/GB2011/051686, are also valid.

The advantage of the charge pump circuit 200 is that there is a very low parasitic capacitance present on the SPAD cathode: only that which results from the coupling capacitor and n⁺ MOS implant, which can both be very small, as well as the negligible contribution from the metal interconnect. The high voltage MOS diodes M_{P3}, M_{P4} isolate the charge pumping capacitors C_{CK1}, C_{CK2} from the SPAD and limits the maximum charge per pulse and hence reduces the after-pulsing probability. This is substantially different from prior active quench circuits using capacitors, where the capacitor is commonly directly connected to the SPAD's moving node, increasing the parasitic capacitance and therefore after-pulsing.

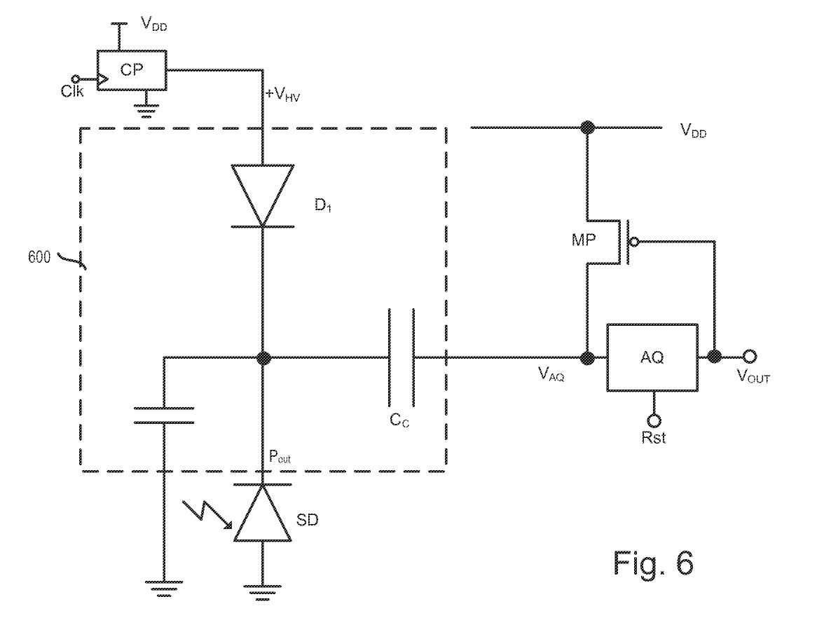

FIG. 6 shows an alternative embodiment of a charge pump final stage 600 for biasing a Deep SPAD SD. In this embodiment, the capacitor C_{C} acts both as the main final stage pump capacitor and as a SPAD coupling capacitor. The voltage V_{HV}, which as before is slightly below the breakdown voltage of the SPAD SD, is connected to capacitor C_{C} via diode D₁. High voltage bias signal V_{HV} may be generated from a charge pump CP (or external high positive voltage supply). As with the previous example, a single charge pump CP may be used to generate the high voltage bias signal V_{HV} for a number of final stages 600 and SPADs, e.g. a whole array comprised within a sensor.

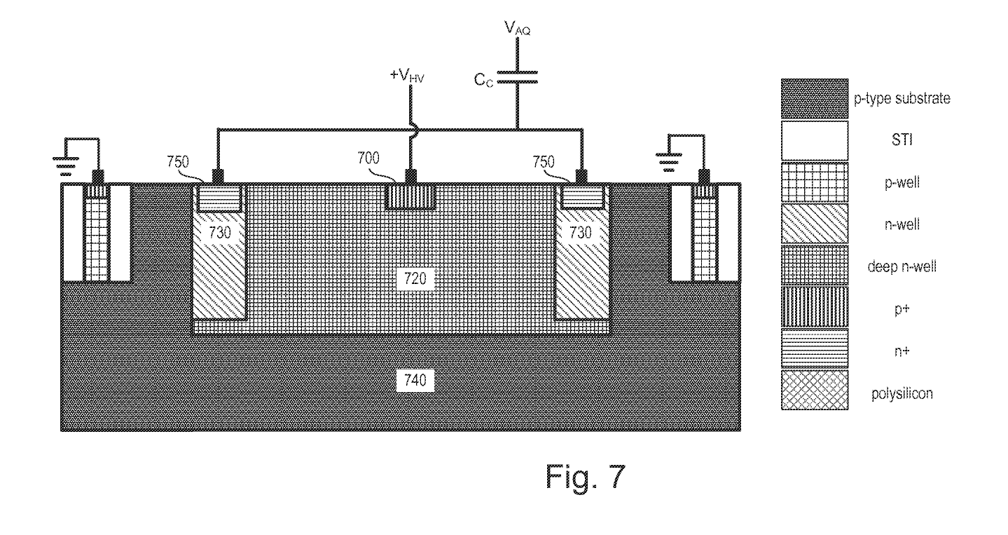

FIG. 7 illustrates (in cross-section) the physical arrangement of the charge pump 600 according to one embodiment. In this embodiment, diode D₁ takes the form of a p⁺ implant 700 (or p⁺ implant inside p-well) inside the n-well 730/DNW 720 of the Deep SPAD (the main junction of the SPAD is the junction between DNW 720 and p-type substrate 740). The p⁺ implant without p-well (as shown) is beneficial to the long wavelength internal quantum efficiency, as the shallow diode p⁺ implant serves to collect less minority carriers than a p-well would prior to detection, reducing sensitivity less.

The high voltage from a charge pump or external supply V_{HV} is connected to the p⁺ implant 700 (or p⁺ in p-well), charging the SPAD DNW 720 to a voltage V_{HV}−V_{diode}, where V_{diode} is the forward-bias turn-on voltage of the diode. A positive pulse of a voltage applied to the other side of capacitor C_{C} (e.g. system voltage V_{DD} applied via MOSFET MP) will pull the DNW 720 to a voltage equal to V_{HV}−V_{diode}+V_{DD}, which should be sufficient to bias the SPAD in Geiger mode: i.e. the voltage levels should be such that (V_{HV}−V_{diode}+V_{DD})>V_{BD}. The positive pulse of amplitude V_{DD} may be initially provided by transistor MP and then subsequently provided by detecting the SPAD falling edge and recharging the capacitor voltage C_{C} by means of an active quench circuit AQ.

A main advantage of this embodiment is compactness, with the diode being formed within the SPAD, at the expense of some quantum efficiency loss in the diode D₁ junction.

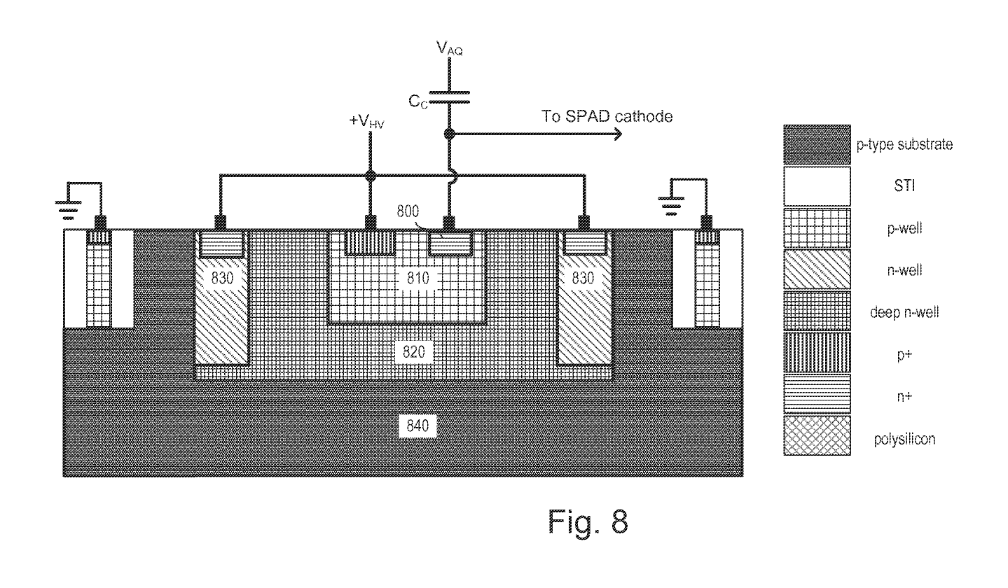

FIG. 8 illustrates an alternative physical arrangement of the charge pump 600 of FIG. 6. In this embodiment Diode D₁ is formed externally by an n⁺ implant 800 within a p-well 810 isolated from the substrate by an n-well/DNW region 820/830. A guard ring around the n-well 830 periphery is constructed in exactly the same fashion as in a Deep SPAD by blocking p-well formation. The DNW 820 and p-well 810 are biased by the charge pump at voltage V_{HV}. The coupling capacitor C_{C} is connected to the n⁺ implant 800 within the p-well.

In normal operation, diode D₁ will experience reverse bias voltages of around V_{DD}, within normal tolerances and far below the breakdown voltage. As before the voltage on the n⁺ implant will be initially V_{HV}−V_{diode}. A rising edge of amplitude V_{DD} is applied to the capacitor C_{C} by a conventional SPAD active quench circuit (or external clock), reverse biasing diode D₁ and raising the SPAD voltage to V_{HV}−V_{diode}+V_{DD}, substantially above the SPAD breakdown. Both p-well and n-well are biased at V_{HV} so there is no issue with breakdown of the p-well/n-well/DNW junctions. The n-well/DNW to p-substrate junction of diode D₁ is constructed in a similar way to the SPAD and so by definition will not experience breakdown when biased at V_{HV}.

Photons triggering the SPAD will cause breakdown, lowering the SPAD voltage below the active quench circuit AQ threshold. The active quench circuit AQ will respond after a suitable delay (quench time) by resetting the capacitor C_{C} to V_{DD} through transistor MP and hence also resetting the SPAD cathode.

In both constructions capacitor C_{C} should be chosen sufficiently large in comparison to the sum of SPAD and diode capacitances such that the V_{DD} pulse is not substantially attenuated at the SPAD cathode. The circuits described herein can be cascaded to generate any voltage higher than the DNW-substrate breakdown voltage up to the n+-p-well breakdown voltage or the gate oxide breakdown, whichever comes first. This could then be used with a high resistance polysilicon quench resistor for applications where high fill factor is important. However, if the voltage is pumped too high eventually inefficiencies will appear due to the large depletion regions formed around the source and drain implants and the difference between the source/drain voltage and the transistor body (p-well).

The circuits described herein differ from traditional capacitively coupled time gated SPAD circuits which arm the SPAD to a high voltage through a coupling capacitor because of the implementation of the high voltage diode between n+ and p-well of the isolated NMOS device. Critically, this keeps the high voltage on the SPAD cathode even when the clock returns low again (minus leakage current), which simplifies the digital circuitry required to reset the SPAD over a traditional time-gated circuit. As with the Deep SPAD invention, this active quench circuit is compatible with any CMOS process which includes a deep n-well mask with an epitaxial layer grown on top of a substrate.

The previously described circuit can be thought of as an “active quench circuit” because although there are no MOS devices present that actively pull down the SPAD to a lower voltage than breakdown, the SPAD is at no point directly connected to a higher DC voltage supply than the breakdown voltage. This negates the need for traditional “active quench” operation where a MOS (or otherwise) switch is implemented to pull the SPAD to below breakdown, because the SPAD pulls itself to below breakdown and there is nothing pulling it up so it remains low, mimicking “active quench” operation.

There are several ways that the circuit can be operated in active recharge mode depending on the desired digital logic. However, each method requires a mechanism of resetting the voltage on the SPAD cathode to account for leakage current through the SPAD which does not trigger breakdown, such as leakage through the guard ring which reduces the excess bias voltage over time. This can simply be achieved by applying a regular clock pulse to the charge pump with sufficient frequency to compensate for the voltage decay due to leakage.

A first, and simplest, method of continuous operation of the SPAD and charge pump circuit is to connect the SPAD enable input SE (FIG. 2) or the gate of device MP (FIG. 6) to a regular clock pulse, which should be sufficient to counteract leakage current and keep the SPAD above breakdown. The exact reset frequency will depend on the leakage current of the device and the efficiency of the charge pump. It would also have to be quite high to maintain a high photon count rate. If a photon arrives, the SPAD breaks down, triggers the output inverter through the coupling capacitor and stays low until the next clock pulse comes along arming it above breakdown again. The disadvantage of this technique is that the dead time is variable from almost 0 ns to the reciprocal of the clock frequency, depending on when the photon arrives between the clock pulses. Additionally, the SPAD could break down during the arming process and stay low for another clock cycle, extending the dead time to two arming periods. The advantage of this technique, however, is that it is very simple to operate.

A second method is more complicated and requires some digital logic to function. The SPAD enable terminal could be connected to a digital state machine of some description which could intelligently perform arming and recharge the SPAD after a breakdown event has been detected. For example, the SPAD could initially be set to the armed, pre-breakdown, state by an application of a SPAD enable pulse. The SPAD would then break down on photon arrival and this would be coupled to the output. The digital logic could then detect the fact that the SPAD has broken down and re-arm the SPAD to a high state after a user-specified time delay. This method has the advantage of a much higher maximum pulse rate and a well-defined dead time of the system. However, it requires more advanced digital logic circuitry. In FIG. 6 such digital logic may be represented by active quench circuit AQ.

A third method is similar to the second, but the initial arming state could be coupled to a correlated light source to enable the SPAD at a similar time to the emission of a light pulse from a ranging system. This would be similar to time-gating but with the advantage that the SPAD would be off when not required. Additionally, the noise performance could be improved through the use of time gating, as discussed above.

An additional potential use of the concepts disclosed herein is to implement a higher fill factor passively quenched system. This could be achieved by using a single NMOS transistor inside its own p-well, biased to behave as a high voltage resistor. This is achieved with an almost identical layout to the charge pump circuits described herein, but with the transistor designed to have a high resistance when on, or biased sufficiently. This may have a smaller area requirement than a polysilicon resistor while remaining high-voltage compatible.

Indeed, the NMOS transistor could be placed inside the SPAD to improve the fill factor. In one embodiment of the Deep SPAD invention, p-well is placed on top of the device to reduce the photon detection probability in the short wavelength range and increase the signal-to-noise of a ranging system operating at 850 nm by increasing the optical filtering of undesired wavelengths. An NMOS quench transistor could be placed inside this isolated p-well and biased to behave as a resistor. This could potentially vastly improve the fill factor of an array of Deep SPADs as there would be no need for separate area to be taken up with a resistor.

The circuit enables the possibility of generating the required high SPAD supply voltage on the same silicon chip which is important for low cost high portability markets, such as the mobile phone market. Since the Deep SPAD has significantly improved sensitivity than existing SPADs, the power consumption of a ranging system would be significantly reduced. The only required external component for a ranging system, 3D camera, or time-correlated lifetime estimation system is a light source such as an LED or laser diode, as all the other components can be fully integrated into CMOS. The ability of a ranging system or 3D camera to be completely integrated into CMOS potentially opens up new portable applications and potential advancements in human-computer interfaces. Additionally, active recharge's ability to offer a more linear response to incident light level is important for certain applications.

Advantages of the circuits disclosed herein in include: the SPAD is recharged only when necessary after a photon trigger and so no clock is necessary; the charge pump output voltage V_{HV} can be shared between multiple SPADs with only the addition of a single diode per SPAD; and the dead time of the SPAD can be controlled by conventional active quench circuitry.

It should be appreciated that the above description is for illustration only and other embodiments and variations may be envisaged without departing from the spirit and scope of the invention. While the above embodiments are disclosed in relation to the deep SPAD, it is equally applicable to any positively driven SPAD implemented in a triple-well CMOS process. Also, while the embodiments all show a p-doped substrate, an n-doped substrate could equally be used, with the doping of all implants reversed accordingly, and all bias voltages changed appropriately.

What is claimed is:

1. A sensor circuit, comprising:
a single photon avalanche diode (SPAD) configured to receive a bias voltage;
a charge pump operable to generate said bias voltage from a first voltage and a second voltage, said bias voltage being higher than a breakdown voltage of the SPAD, each of said first voltage and said second voltage being lower than the breakdown voltage of the SPAD;
wherein said charge pump is operable to isolate the bias voltage on an electrode of the SPAD, thereby biasing said SPAD.

2. The sensor circuit as claimed in claim 1, wherein said charge pump and said SPAD are integrated on a common substrate.

3. The sensor circuit as claimed in claim 2, wherein said common substrate forms one half of a multiplication junction for the SPAD.

4. The sensor circuit as claimed in claim 2, wherein said charge pump is operable to stack the first and second voltages on one of its nodes so as to generate said bias voltage.

5. The sensor circuit as claimed in claim 4, wherein said charge pump comprises at least one diode at its output, isolated from said substrate, with said first and second voltages being stacked on said diode.

6. The sensor circuit as claimed in claim 5, wherein said first and second voltages are stacked such that a parasitic junction breakdown voltage limit is not exceeded.

7. The sensor circuit as claimed in claim 5, wherein said at least one diode is integrated within the SPAD.

8. The sensor circuit as claimed in claim 7, wherein said diode comprises a diode implant formed within an implant which forms one half of a multiplication junction of the SPAD.

9. The sensor circuit as claimed in claim 5, wherein said diode is comprised within a separate well implant.

10. The sensor circuit as claimed in claim 5, wherein said first voltage is applied to the electrode of the SPAD via said diode; said circuit comprising a capacitor operable to DC-isolate output devices from said bias voltage, wherein said second voltage is applied to the electrode of the SPAD via said capacitor.

11. The sensor circuit as claimed in claim 5, wherein said node on which said voltage is stacked in order to generate the bias voltage comprises a drain or source implant of a MOSFET device configured as said diode.

12. The sensor circuit as claimed in claim 11, wherein said first and second voltages are stacked such that a transistor gate oxide voltage limit of the MOSFET device is not exceeded.

13. The sensor circuit as claimed in claim 11, wherein said charge pump comprises a plurality of MOSFET devices isolated from said substrate in a well implant.

14. The sensor circuit as claimed in claim 13, wherein the charge pump comprises one of NMOS transistors isolated from the substrate inside a p-well or PMOS transistors isolated from the substrate inside an n-well.

15. The sensor circuit as claimed in claim 1, wherein said charge pump is operable in alternate phases of charging a capacitance with said first voltage and outputting the voltage stored on said capacitance in series with said second voltage.

16. The sensor circuit as claimed in claim 15, wherein the charge pump comprises two capacitances and four MOSFET devices, a first two of said MOSFET devices being operable to selectively connect the first voltage to respective ones of said capacitances and a second two of said MOSFET devices acting as diodes being operable to isolate the voltage on the SPAD cathode from the output of said output stage.

17. The sensor circuit as claimed in claim 1, wherein the charge pump is enabled at periodic intervals.

18. The sensor circuit as claimed in claim 17, wherein said periodic intervals are selected to be sufficient to counteract leakage from the SPAD cathode.

19. The sensor circuit as claimed in claim 17, further comprising a circuit configured to sense that the SPAD has triggered and, on sensing the trigger, actively enable the charge pump.

20. The sensor circuit as claimed in claim 19, further comprising an additional circuit configured to enable a correlated emission source.

21. The sensor circuit as claimed in claim 1, wherein the bias voltage is stored on a capacitance of the SPAD, said capacitance comprising one of a junction capacitance, a coupling capacitance, and a parasitic capacitance.

22. The sensor circuit as claimed in claim 1, wherein said charge pump isolates the bias voltage on a cathode of the SPAD.

23. The sensor circuit as claimed in claim 1, wherein said second voltage is provided by a periodic clock signal.

24. The sensor circuit as claimed in claim 23, wherein said charge pump is double-sided with said second voltage being provided by two non-overlapping periodic clock signals, the charge pump operable to pump on positive and negative edges of one of said clock signals.

25. The sensor circuit as claimed in claim 1, wherein said charge pump provides a biasing voltage for a further transistor, connected between said charge pump and a cathode of the SPAD, said further transistor being configured to operate as a quenching resistor.

26. The sensor circuit as claimed in claim 25, wherein said further transistor is provided within a well implant comprised within said SPAD.

27. The sensor circuit as claimed in claim 1, further comprising:
a plurality of SPAD's;
a plurality of charge pumps coupled to the plurality of SPAD's; and
an additional charge pump operable to generate said first voltage for application to the plurality of charge pumps.

28. The sensor circuit as claimed in claim 27, wherein each SPAD is connected to a dedicated charge pump.
